(19) United States
(12) Patent Application Publication
(10) Pub. No.: US 2008/0164143 A1
(43) Pub. Date: Jul. 10, 2008

(54) FILM FORMATION APPARATUS, FILM FORMATION METHOD, MANUFACTURING METHOD AND TITANIUM FILM

(75) Inventor: TOSHIYUKI ARAKI, TOKYO (JP)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: ADVANTEST CORPORATION, TOKYO (JP)

(21) Appl. No.: 11/777,295

(22) Filed: Jul. 13, 2007

Related U.S. Application Data
(63) Continuation of application No. PCT/JP2006/300657, filed on Jan. 18, 2006.

(30) Foreign Application Priority Data
Jan. 18, 2005 (JP) 2005-010893

(51) Int. Cl. C23C 14/24; C23C 14/34

(52) U.S. Cl. 204/192.1; 204/298.03

(57) ABSTRACT

A film formation apparatus that forms a metal film on a substrate is provided. The film formation apparatus includes: a chamber that holds therein the substrate; a material holding section that holds a metal material as a material for the metal film in the chamber; a film formation section that forms the metal film on the substrate by using the metal material; an introduction section that introduces gas into the chamber; and a partial pressure control section that controls the partial pressure of the gas in the chamber to cause the film formation section to form the metal film having a desired density.

### CROSS REFERENCE TO RELATED APPLICATION

This is a continuation application of PCT/JP2006/300657 filed on Jan. 18, 2006 which claims priority from a Japanese Patent Application NO. 2005-010893 filed on Jan. 18, 2005, the contents of which are incorporated herein by reference.

### BACKGROUND

1. Technical Field

The present invention relates to a film formation apparatus, a film formation method, a manufacturing method and a titanium film. Particularly, the present invention relates to a film formation apparatus that forms a metal film on a substrate, a film formation method, a manufacturing method and a titanium film manufactured by the manufacturing method.

2. Related Art

Generally, a method for forming a metal film on a substrate by using a vacuum evaporation method and a sputtering method has been known. For example, when a titanium film is formed by using the vacuum evaporation method, titanium held in a chamber is heated by such as electron beam and evaporated, and then, the evaporated titanium particles are deposited on the substrate held in the chamber.

Here, any prior art document is not found at this time, so that the description about it is omitted.

### SUMMARY

For example, when the chamber is vented, the amount of water vapor contained in air introduced into the chamber and the time length for venting the chamber do not necessarily stay constant. Therefore, the amount of water adsorbed to the inner wall of the chamber could be different every time a metal film is formed. Then, in a film formation process, any particle such as a hydrogen atom or an oxygen atom which exists in the chamber other than metal particles in forming a film is also introduced into the metal film. Therefore, when the amount of water vapor in the chamber in forming a film is changed, the amount of particles derived from the water vapor introduced into the metal film is changed, so that the density of the formed metal film could be varied.

In addition, in order to keep the degree of vacuum in the chamber high, moisture can be prevented from being adsorbed to the wall surface of the chamber in venting by heating the wall surface of the chamber. The above described method can provide temporarily a high film density, however, the rate for evaporating gas from the wall surface of the chamber is increased during repeatedly forming a film, so that the film density could be changed. Moreover, the method can not form a film having a low density.

Accordingly, it is an advantage of the invention to provide a film formation apparatus, a film formation method, a manufacturing method and a titanium film which are capable of solving the above-mentioned problem. This advantage may be achieved through the combination of features described in independent claims of the invention. Dependent claims thereof specify preferable embodiments of the invention.

In order to solve the above described problems, a first aspect of the present invention provides a film formation apparatus that forms a metal film on a substrate. The film formation apparatus includes: a chamber that holds therein the substrate; a material holding section that holds a metal material as a material for the metal film in the chamber; a film formation section that forms the metal film on the substrate by using the metal material; an introduction section that introduces gas into the chamber; and a partial pressure control section that controls the partial pressure of the gas in the chamber to cause the film formation section to form the metal film having a desired density. The metal film may be a titanium film or a titanium alloy film.

The film formation apparatus as set forth in claim 1, wherein the introduction section introduces water vapor as the gas into the chamber. The partial pressure control section may set a predetermined value between about 4×10⁻⁵ Pa and about 4×10⁻³ Pa as the partial pressure of the gas and cause the film formation section to form a titanium film having the desired density between about 4.2 g/cc and about 2.6 g/cc. In addition, the partial pressure control section may set the partial pressure of the gas to a predetermined value between about 2×10⁻⁵ Pa and about 1×10⁻¹ Pa and cause the film formation section to form a titanium film having the desired density between about 4.3 g/cc and about 1.5 g/cc.

The film formation section may form the titanium film on the substrate by the vacuum evaporation method. The film formation apparatus further includes a partial pressure measuring section that measures the partial pressure of the gas in the chamber. The partial pressure control section may control the partial pressure of the gas in the chamber by controlling the flow rate of the gas from the introduction section to the chamber based on the measured partial pressure of the gas.

The film formation apparatus further includes a pump that vents the chamber and a partial pressure measuring section that measures the partial pressure of the gas in the chamber. The partial pressure control section may control the partial pressure of the gas in the chamber by controlling the exhaust velocity of the pump based on the measured partial pressure of the gas. The partial pressure control section may control the partial pressure of the gas in the chamber such that the measured partial pressure of the gas is a preset partial pressure.

A second aspect of the present invention provides a film formation method for forming a metal film on a substrate. The method includes the steps of: holding the substrate inside a chamber; holding a metal material as a material for the metal film in the chamber by a material holding section; forming the metal film on the substrate by using the metal material; introducing gas into the chamber by an introduction section; and controlling the partial pressure of the gas in the chamber to cause a film formation section to form a metal film having a desired density. The metal film may be a titanium film or a titanium alloy film.

The film formation method further includes a step of measuring the partial pressure of the gas in the chamber. The step of controlling the partial pressure may control the partial pressure of the gas in the chamber by controlling a flow rate of the gas from the introduction section into the chamber in the step of introducing based on the measured partial pressure of the gas.

The film formation method further includes a step of measuring the partial pressure of the gas in the chamber. The steps of controlling the partial pressure may control the partial pressure of the gas in the chamber by controlling the exhaust velocity of a pump that exhausts the chamber based on the measured partial pressure of the gas.

A third aspect of the present invention provides a manufacturing method for manufacturing a substrate having a surface on which a metal film is formed. The manufacturing method includes the steps of: holding a substrate in a chamber; holding a metal material as a material for the metal film in the chamber; forming the metal film on the substrate by using the metal material; introducing gas into the chamber; and controlling the partial pressure of the gas in the chamber to form the metal film having a desired density by the step of forming the film. The metal film may be a titanium film or a titanium alloy film.

A forth aspect of the present invention provides a titanium film manufactured by the above described manufacturing method.

Here, all necessary features of the present invention are not listed in the summary of the invention. The sub-combinations of the features may become the invention.

### BRIEF DESCRIPTION OF THE DRAWINGS

FIG. 1 shows an example of configuration of a film formation apparatus 10 according to an embodiment of the present invention;

FIG. 2 shows an example of correlation between the partial pressure of water vapor and the density, of a titanium film in the film formation apparatus 10 according to an embodiment of the present invention;

FIG. 3 shows an example of the concentration of a hydrogen atom and an oxygen atom in the titanium film formed by the film formation apparatus 10 according to an embodiment of the present invention;

FIG. 4 shows a change of the density of the titanium film formed by the film formation apparatus 10 according to an embodiment of the present invention in the thickness direction;

FIG. 5 shows a change of the density of the titanium film in the thickness direction when the titanium film is formed without controlling the partial pressure of water vapor by a sputtering method; and

FIG. 6 is a flowchart shoving an example of flow of processing in a film formation method by using the film formation apparatus 10 according to an embodiment of the present invention.

### BEST MODE FOR CARRYING OUT THE INVENTION

### Description of Exemplary Embodiments

The invention will now be described based on preferred embodiments, which do not intend to limit the scope of the invention, but exemplify the invention. All of the features and the combinations thereof described in the embodiments are not necessarily essential to the invention.

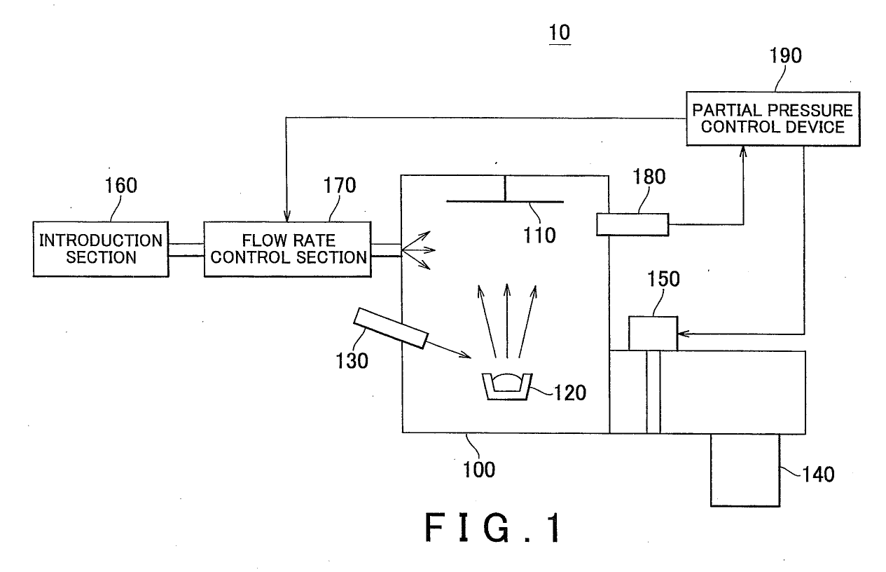

FIG. 1 shows an example of configuration of a film formation apparatus 10 according to the present embodiment. The film formation apparatus 10 according to the present embodiment aims to form a metal film having a desired density on a substrate by controlling the partial pressure of gas in a chamber 100 during introducing the gas such as water vapor into the chamber In the present embodiment, the film formation apparatus 10 forms a metal film on a substrate by means of a vacuum evaporation method. Alternatively, the film formation apparatus 10 may form a metal film on a substrate by means of a sputtering method.

The film formation apparatus 10 includes the chamber 100, a substrate holder 110, a material holding section 120, a film formation section 130, a pump 140, a conductance valve 150, an introduction section 160, a flow rate control section 170, a partial pressure measuring section 180 and a partial pressure control device 190.

The chamber 100 holds therein the substrate on which a metal film is formed by the substrate holder 110. The material holding section 120 holds a metal material as a material for the metal film formed on the substrate in the chamber 100. Here, the metal material may be such as titanium, or may be metal having the gettering effect. The film formation section 130 forms the metal film on the substrate held by the substrate holder 110 by using the metal material held by the material holding section 120.

The pump 140 vents the chamber 100. The conductance valve 150 is disposed between the chamber 100 and the pump 140 and controls the exhaust velocity of the pump 140. The introduction section 160 introduces gas used for controlling the film density into the chamber 100 through the flow rate control section 170. Here, the gas may be such as water vapor or may be gas such as oxygen gas, hydrogen gas and organic material. The flow rate control section 170 controls the flow rate of the gas from the introduction section 160 to the chamber 100. The flow rate control section 170 may be such as a mass flow controller by using a digital mass flow sensor.

The partial pressure measuring section 180 measures the partial pressure of the gas in the chamber 100 which is introduced by the introduction section 160. Then, the partial pressure measuring section 180 outputs the measured result of the partial pressure of the gas to the partial pressure control device 190. The partial pressure control device 190 controls the partial pressure of the gas introduced by the introduction section 160 in the chamber 100 to cause the film formation section 130 to form a metal film having a desired density. Here, the partial pressure control device 190 may control the exhaust velocity of the pump 140 by using the conductance valve 150 to control the partial pressure of the gas. In addition, the partial pressure control device 190 may control the flow rate of the gas from the introducing section 160 to the chamber 100 by using the flow rate control section 170 to control the partial pressure of the gas. Here, the conductance valve 150, the flow rate control section 170 and the partial pressure control device 190 as shown in the figure are examples of the partial pressure control section in the present invention.

The film formation apparatus 10 according to the present embodiment can form a metal film such as a titanium film having a desired density on a substrate by controlling the partial pressure of gas such as water vapor in the chamber 100 during introducing the gas into the chamber 100. Particularly, titanium has the characteristic that it easily introduces therein hydrogen or oxygen, and water molecules, hydrogen molecules and/or oxygen molecules collide with the titanium particles when the partial pressure of the water vapor is increased in the chamber 100, so that the size of the particle is enlarged. Therefore, it is difficult to hold the film density constant. The film formation apparatus 10 according to the present embodiment can control the partial pressure of the gas in the chamber during forming the film, so that a film of titanium which has been conventionally difficult to control the density can be formed with a predetermined density.

Moreover, in a conventional deposition apparatus by using the vacuum evaporation method, the water partial pressure in the chamber is reduced as soon as starting to form the film. It is assumed that the phenomenon occurs due to the gettering effect of the titanium. For example, when 100 nm of the titanium film is formed, the water partial pressure in the chamber is reduced by about double digits. The film formation apparatus 10 according to the present embodiment can hold the water partial pressure constant by introducing water vapor into the chamber 100 during forming the film, so that homogenous titanium films can be formed.

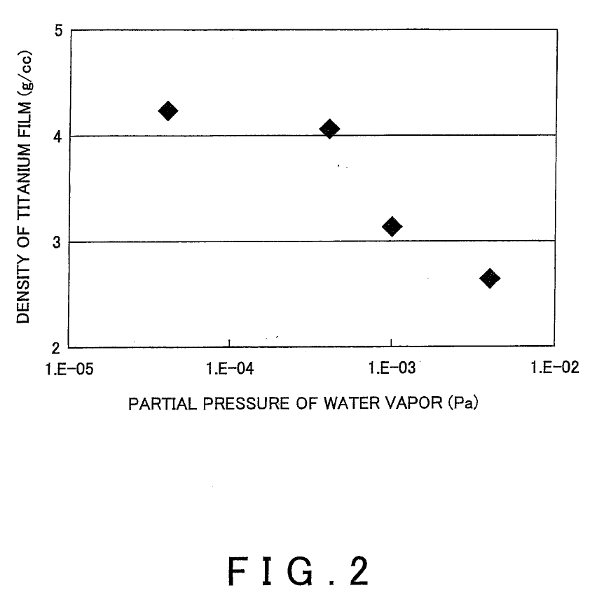

FIG. 2 shows an example of correlation between the partial pressure of water vapor and the density of a titanium film in the film formation apparatus 10 according to the present embodiment. The film density of the titanium film indicated by the vertical axis is the mass of the titanium contained in the titanium film per unit volume which is measured by Rutherford back scattering analysis method (RBS method) in FIG. 2. For example, the film formation apparatus 10 can more increase the density of the titanium film by reducing the partial pressure of the water vapor in the chamber 100. Meanwhile, the density of the titanium film can be more reduced by increasing the partial pressure of the water vapor in the chamber 100. For example, the film formation apparatus 10 controls the partial pressure of the water vapor in the chamber 100 so as to be about 4×10⁻⁵ Pa, about 4×10⁻⁴ Pa, 1×10⁻³ Pa and 4×10⁻³ Pa, respectively to form the titanium film having the density of about 4.2 gm, about 4 gm, about 3.2 gm and about 2.6 gm per cc on the substrate.

Here, it is difficult for the film formation apparatus 10 by using the vacuum evaporation method to form a film when the partial pressure of the water vapor is more than about 1×10⁻¹ Pa. Thus, the partial pressure of the water vapor is increased up to about 1×10⁻¹ Pa, so that a titanium film having a low density of about 1.5 gm per cc can be formed. In addition, in the film forming apparatus 10 by using the vacuum evaporation method, water molecules are adsorbed to the inner wall of the chamber 100 to a certain extent, so that it is difficult to reduce the partial pressure of the water vapor to a value less than such as about 4×10⁻⁵ Pa by using a general film formation processing. However, the film formation apparatus 10 performs a film formation processing after reducing the water molecules previously adsorbed to such as the inner wall in the chamber 100, so that the partial pressure of the water vapor can be controlled to a low value such as about 2×10⁻⁵ Pa. Moreover; the film formation apparatus 10 can form a titanium film having the density of about 4.5 g/cc (the concentration of the titanium is about 100%).

As described above, the partial pressure control device 190 controls the partial pressure of the water vapor in the chamber 100 which is measured by the partial pressure measuring section 180 so as to be corresponding to a desired film density. Thereby the titanium film having the desired density can be accurately formed on the substrate. In addition, even if the amount of water adsorbed to the inner wall of the chamber 100 is fluctuated, the film formation apparatus 10 can hold the partial pressure of the gas in the chamber 100 constant by introducing or venting the amount of the water vapor more than that of the fluctuation. Therefore, a metal film having a desired density can be accurately formed on the substrate.

Moreover, in the partial pressure control device 190, a predetermined value between about 4×10⁻⁵ Pa and about 4×10⁻³ Pa is set as the partial pressure of the gas, so that the film formation section 130 can form the titanium film having a desired density between about 4.2 g/cc and about 2.6 g/cc. Here, the partial pressure control device 190 can cause the film formation section 130 to form the titanium film having the desired density between about 4.2 g/cc and about 2.6 g/cc provided that the partial pressure of the gas can be set within a region including the range between about 4×10⁻⁵ Pa and about 4×10⁻³ Pa.

In the same way, the partial pressure control device 190 can cause the film formation section 130 to form a titanium film having a desired density between about 4.3 g/cc and about 1.6 g/cc by setting a predetermined value between about 2×10⁻⁵ Pa and about 1×10⁻¹ Pa. Here, the partial pressure control device 190 can cause the film formation section 130 to form a titanium film having the desired density between about 4.3 g/cc and about 1.6 g/cc provided that the partial pressure of the gas can be set within a region including the range between about 2×10⁻⁵ Pa and about 1×10⁻³ Pa.

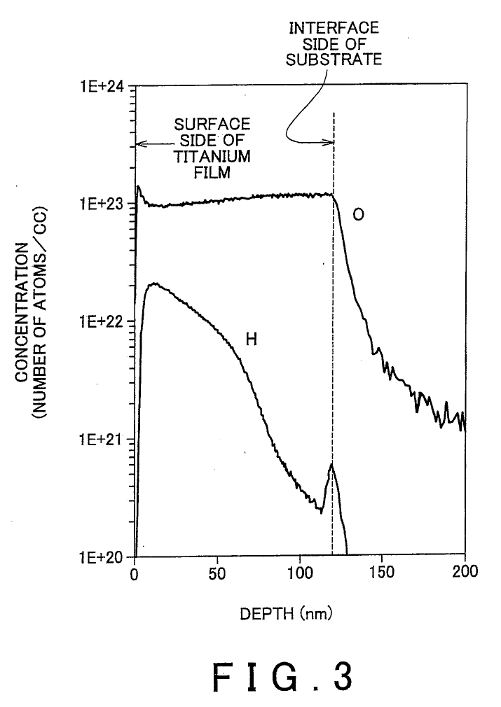

FIG. 3 shows an example of the concentration of a hydrogen atom and an oxygen atom in the titanium film formed by the film formation apparatus 10 according to the present embodiment. Specifically, FIG. 3 shows a result obtained by performing a secondary-ion mass analysis (SIMS analysis) on the titanium film formed by the film formation section 130 by using the vacuum evaporation method while the partial pressure control device 190 controls the water partial pressure in the chamber 100 to be 4×10⁻³ Pa. Here, the horizontal axis indicates the thickness direction (depthwise direction) extending from the surface of the titanium film toward the substrate, and the vertical axis indicates the number of atoms per cc of the hydrogen atoms and the oxygen atoms by the depth. Therefore, it is understood that the film formation apparatus 10 can form a titanium film compounded of hydrogen and oxygen by forming the film with increasing the water partial pressure in the chamber 100.

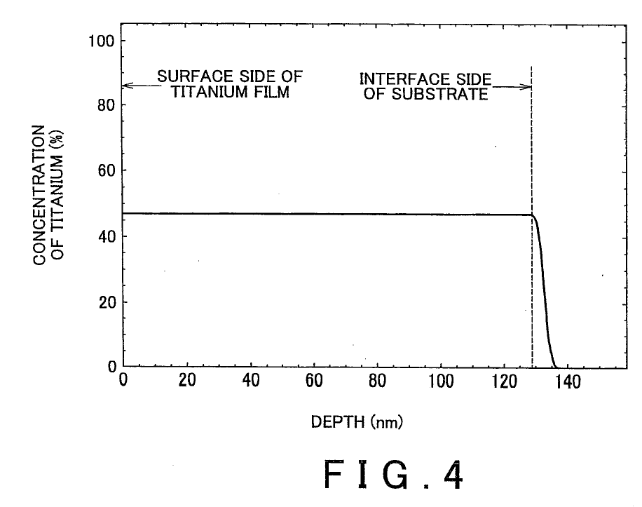

FIG. 4 shows a change of the concentration of titanium in the titanium film formed by the film formation apparatus 10 according to an embodiment of the present invention in the thickness direction. Specifically, FIG. 4 shows a result obtained by performing RBS analysis on the titanium film formed by the film formation section 130 by using the vacuum evaporation method while the partial pressure control device 190 controls the water partial pressure in the chamber 100 to be 4×10⁻³ Pa. Here, the horizontal axis indicates the thickness direction (depthwise direction) extending from the surface of the titanium film toward the substrate, and the vertical direction indicates the concentration of titanium by the depth.

For the convenience of the analysis, FIG. 4 indicates the concentration of titanium under the assumption that the titanium film contains only titanium and oxygen. Here, as the result of the RBS analysis, only titanium and oxygen among atoms are contained in the titanium film at the concentration of equal to or more than 1%, and the percentage of hydrogen and the other atoms is small, so that it can be admitted that the concentration of the titanium indicated by the graph is substantially accurate. As described above, it is understood that the film formation apparatus 10 can form each titanium film having the homogeneous density by forming the titanium film during controlling the water partial pressure in the chamber 100 to be a predetermined value.

In the same way, the titanium film is formed during controlling the water partial pressure in the chamber 100 to be 4×10⁻⁵ Pa, 4×10⁻⁴ Pa and 1×10⁻³ Pa, respectively and then, the formed titanium film is analyzed. As the result of that, homogeneous titanium films containing titanium at the concentration of about 92%, 84%, and 62% respectively can be formed. As described above, the film formation apparatus 10 according to the present embodiment can be form the homogeneous titanium film having each desired density by controlling the partial pressure of the water vapor to be a predetermined value.

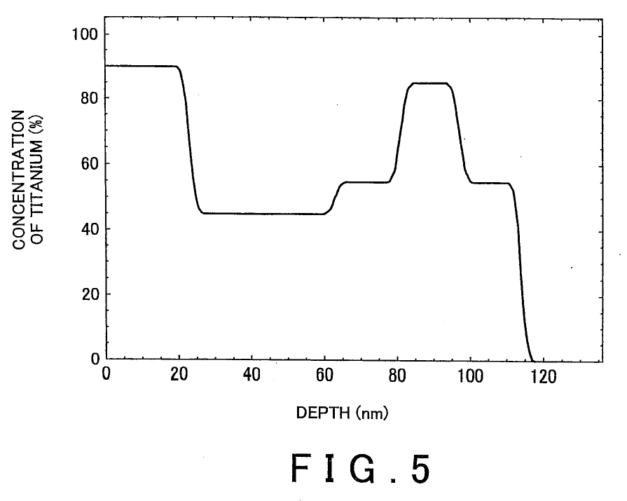

FIG. 5 shows a change of the density of the titanium film in the thickness direction when the titanium film is formed without controlling the partial pressure of water vapor by a sputtering method. Specifically, FIG. 5 shows a result obtained by performing RBS analysis on the titanium film formed without controlling the water partial pressure by the spattering method. Here, the horizontal direction indicates the thickness direction (depthwise direction) extending from the surface of the titanium film toward the substrate, and the vertical axis indicates the concentration of titanium by the depth.

It is understood that inhomogeneous titanium films could be formed because the water partial pressure in the chamber is changed thereby changing the concentration of titanium when the water partial pressure is not controlled as shown in the figure. In addition, note that a part of the cause to change the film density is to use the sputtering method instead of the vacuum evaporation method.

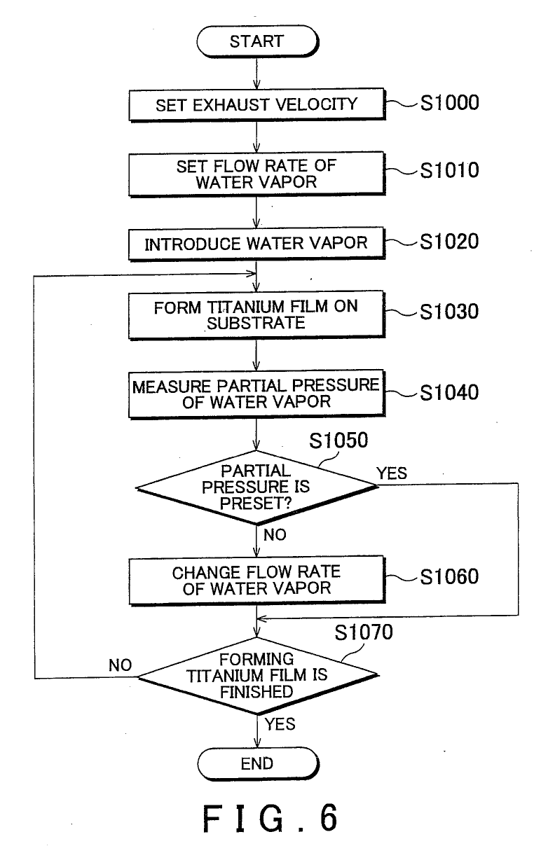

FIG. 6 is a flowchart showing an example of flow of processing in a film formation method by using the film formation apparatus 10 according to the present embodiment. Firstly, the partial pressure control device 190 controls the conductance valve 150 to set the exhaust velocity of the pump 140 to a predetermined initial setting value (S1000). Next, the partial pressure control device 190 controls the flow rate control section 170 to set the flow rate of the water vapor introduced from the introduction section 160 to the chamber 100 to a predetermined initial setting value (S1010). Next, the introduction section 160 introduces water vapor into the chamber 100 through the flow rate control section 170 (S1020). Next, the film formation section 130 forms a metal film on the substrate by using a metal material held by the material holding section 120 (S1030). For example, when the film formation apparatus 10 forms a titanium film by using the vacuum evaporation method, the film formation section 130 irradiates titanium held by the material holding section 120 with electron beam to evaporate the titanium. Then, the film formation section 130 adsorbs the evaporated titanium particles onto the substrate held by the substrate holder 110 to form the metal film.

Next, the partial pressure measuring section 180 measures the partial pressure of the water vapor in the chamber 100 (S1040). Here, the partial pressure control device 190 judges whether the partial pressure of the water vapor measured by the partial pressure measuring section 180 is approximately corresponding to the partial pressure preset in order to form a titanium film having a predetermined density (S1050). Then, judging that the measured partial pressure is not approximately corresponding to the preset partial pressure (S1050: No), the partial pressure control device 190 changes the flow rate of the water vapor introduced from the introduction section 160 to the chamber 100 by using the flow rate control section 170 (S1060). Specifically, when the measured partial pressure is lower than the preset partial pressure, the partial pressure control device 190 may control the flow rate control section 170 so as to increase the flow rate of water vapor. Meanwhile, when the measured partial pressure is higher than the preset partial pressure, the partial pressure control device 190 may control the flow rate control section 170 so as to reduce the flow rate of water vapor. Next, the film formation apparatus 10 judges whether it terminates forming a titanium film (S1070). Then, judging that it does not terminate forming the titanium film (S1070: No), the film forming apparatus 10 returns the processing to S1030 and continues to form the titanium film.

As described above, the film formation apparatus 10 according to the present embodiment can control the partial pressure of the water vapor in the chamber 100 during introducing the water vapor into the chamber 100, so that a titanium film having a desired density can be accurately formed on the substrate.

Hereinbefore, it has been described as the partial pressure control device 190 controls the partial pressure of the water vapor in the chamber 100 by controlling the flow rate of the water vapor introduced from the introduction section 160 to the chamber 100 without changing the exhaust velocity of the pump 140 in S1050 shown in FIG. 6. Alternatively, the partial pressure control device 190 may control the partial pressure of the water vapor in the chamber 100 by controlling the exhaust velocity of the pump 140. Specifically, when the partial pressure of the water vapor measured by the partial pressure measuring section 180 is lower than the preset partial pressure, the partial pressure control device 190 may more reduce the exhaust velocity of the pump 140 by more narrowing the opening of the conductance valve 150, for example. Meanwhile, when the measured partial pressure of the water vapor is higher than the preset partial pressure, the partial pressure control device 190 may more increase the exhaust velocity of the pump 140 by more enlarging the opening of the conductance valve, for example.

In addition, the partial pressure control device 190 may control both of the flow rate of the water vapor introduced from the introduction section 160 to the chamber 100 and the exhaust velocity of the pump 140 to control the partial pressure of the water vapor in the chamber 100.

Moreover; the film formation apparatus 10 may use the above described film formation method in order to form a wiring pattern by forming the pattern of the titanium film on the substrate, or in order to form a mirror by forming the titanium film on the substrate. In this case, the partial pressure control device 190 can control the density of the titanium film so as to set a parameter to be controlled such as the electric resistance of the wiring pattern or reflective index of the minor to a predetermined value by controlling the partial pressure of the gas in the chamber 100.

For example, a titanium film is previously and experimentally formed by the film formation apparatus 10 at the partial pressure of each of a plurality of gases and measures the parameter value for each of them, so that the relationship between the partial pressure of the gas and the parameter value can be obtained. In addition, the density of the titanium film formed at each partial pressure is previously measured, so that the relationship between the partial pressure of the gas and the film density can be obtained. The titanium film having a low density formed as described above may be used as such as a nonglare-treated protection film. Moreover; such titanium film having a low density can be used as hydrogen absorber because of being capable of adsorbing hydrogen with a high adsorption ratio, so that it can be applied to such as a fuel cell.

The film formation apparatus 10 may further include a memory that previously store a relationship between the partial pressure of the gas and the parameter value obtained as described above and so forth, and an input section that inputs the designation of the parameter value of the titanium film to be formed. Then, the partial pressure control device 190 in the film formation apparatus 10 may calculate the partial pressure of the gas corresponding to the designated parameter value by using the contents of the memory and control the partial pressure of the gas in the chamber 100 during forming the film to the calculated value. Alternatively, the film formation apparatus 10 may use a function or an approximate expression for calculating the partial pressure of the gas from the parameter value, which is obtained based on the relationship between the partial pressure of the gas and the parameter value obtained as described above. The film formation apparatus 10 can accurately control the diffusion profile by controlling the density of a titanium film formed on the substrate in order to diffuse titanium as well as described above. In addition, the titanium film formed as described above is used to dope titanium on a wafer, so that a device required for deeply diffusing titanium can be manufactured.

As described above, the film formation apparatus 10 according to the present embodiment can accurately form a titanium film having a desired density on a substrate by controlling the partial pressure of the water vapor in the chamber to be a preset partial pressure. Therefore, the film formation apparatus 10 can provide a method for manufacturing a substrate on which a titanium film having a desired density is formed by using the above described film formation method.

Here, in the above-described embodiments, the titanium film has been described as an example of metal film. However, the metal film may be a metal film other than the titanium film. La addition, the metal film may be a titanium alloy film.

While the present invention has been described with the embodiment, the technical scope of the invention not limited to the above described embodiment. It is apparent to persons skilled in the art that various alternations and improvements can be added to the above-described embodiment. It is apparent from the scope of the claims that the embodiment added such alternation or improvements can be included in the technical scope of the invention.

As described above, according to an embodiment(s) of the present invention, a metal film having a desired density can be accurately formed on a substrate.

What is claimed is:

1. A film formation apparatus that forms a metal film on a substrate, comprising:
a chamber that holds therein the substrate;
a material holding section that holds a metal material as a material for the metal film in the chamber;
a film formation section that forms the metal film on the substrate by using the metal material;
an introduction section that introduces gas into the chamber; and
a partial pressure control section that controls the partial pressure of the gas in the chamber to cause the film formation section to form the metal film having a desired density.

2. The film formation apparatus as set forth in claim 1 wherein the metal film is a titanium film or a titanium alloy film.

3. The film formation apparatus as set forth in claim 2, wherein the introduction section introduces water vapor as the gas into the chamber.

4. The film formation apparatus as set forth in claim 3, wherein the partial pressure control section sets a predetermined value between about 4×10⁻⁵ Pa and about 4×10⁻³ Pa as the partial pressure of the gas and causes the film formation section to form a titanium film having the desired density between about 4.2 g/cc and about 2.6 g/cc.

5. The film formation apparatus as set forth in claim 3, wherein the partial pressure control section sets the partial pressure of the gas to a predetermined value between about 2×10⁻⁵ Pa and about 1×10⁻¹ Pa and causes the film formation section to form a titanium film having the desired density between about 4.3 g/cc and about 1.5 g/cc.

6. The film formation apparatus as set forth in any one of claim 2, wherein the film formation section forms the titanium film on the substrate by an evaporation method.

7. The film formation apparatus as set forth in claim 2 further comprising a partial pressure measuring section that measures the partial pressure of the gas in the chamber,
the partial pressure control section controls the partial pressure of the gas in the chamber by controlling the flow rate of the gas from the introduction section to the chamber based on the measured partial pressure of the gas.

8. The film formation apparatus as set forth in claim 2 further comprising:
a pump that vents the chamber; and
a partial pressure measuring section that measures the partial pressure of the gas in the chamber,
the partial pressure control section controls the partial pressure of the gas in the chamber by controlling an exhaust velocity of the pump based on the measured partial pressure of the gas.

9. The film formation apparatus as set forth in claim 3, wherein the partial pressure control section controls the partial pressure of the gas in the chamber such that the measured partial pressure of the gas is a preset partial pressure.

10. A film formation method for forming a metal film on a substrate, comprising:
holding the substrate inside a chamber;
holding a metal material as a material for the metal film in the chamber by a material holding section;
forming the metal film on the substrate by using the metal material;
introducing gas into the chamber by an introduction section; and
controlling a partial pressure of the gas in the chamber to cause a film formation section to form the metal film having a desired density.

11. The film formation apparatus as set forth in claim 10, wherein the metal film is a titanium film or a titanium alloy film.

12. The film formation method as set forth in claim 11 further comprising a step of measuring the partial pressure of the gas in the chamber,
the step of controlling the partial pressure controls the partial pressure of the gas in the chamber by controlling a flow rate of the gas from the introduction section into the chamber in the step of introducing based on the measured partial pressure of the gas.

13. The film formation method as set forth in claim 11 further comprising a step of measuring a partial pressure of the gas in the chamber,
the step of controlling the partial pressure controls the partial pressure of the gas in the chamber by controlling the exhaust velocity of a pump that exhausts the chamber based on the measured partial pressure of the gas.

14. A manufacturing method for manufacturing a substrate having a surface on which a metal film is formed, comprising:
holding a substrate in a chamber;
holding a metal material as a material for the metal film in the chamber;
forming the metal film on the substrate by using the metal material;
introducing gas into the chamber; and
controlling the partial pressure of the gas in the chamber to form the metal film having a desired density by the step of forming the film.

15. The film formation apparatus as set forth in claim 14, wherein the metal film is a titanium film or a titanium alloy film.

16. A titanium film manufactured by the manufacturing method as set forth in claim 15.
